(19) United States
(12) Patent Application Publication
(10) Pub. No.: US 2024/0405090 A1
(43) Pub. Date: Dec. 5, 2024

(54) SEMICONDUCTOR DEVICE

(71) Applicant: SAMSUNG ELECTRONICS CO., LTD., Suwon-si (KR)

(72) Inventors: Seong Heum CHOI, Suwon-si (KR); Jeong Hoon SEO, Suwon-si (KR); Rak Hwan KIM, Suwon-si (KR); Chung Hwan SHIN, Suwon-si (KR); Do Sun LEE, Suwon-si (KR)

(73) Assignee: SAMSUNG ELECTRONICS CO., LTD., Suwon-si (KR)

(21) Appl. No.: 18/390,782

(22) Filed: Dec. 20, 2023

(30) Foreign Application Priority Data
Jun. 2, 2023 (KR) 10-2023-0071614

(51) Int. Cl. H01L 29/45; H01L 21/285; H01L 29/40

(52) U.S. Cl. CPC H01L 29/45; H01L 21/28518; H01L 29/401

(57) ABSTRACT

A semiconductor device is provided. The semiconductor device includes: a semiconductor device including: an active pattern extending in a first direction; a gate structure including a gate electrode extending in a second direction and a gate spacer on the active pattern, wherein the gate electrode and the gate spacer are spaced apart from each other in the first direction; a source/drain pattern on the active pattern; a contact barrier layer on the source/drain pattern; and a contact filling layer on the contact barrier layer. An uppermost point of the contact barrier layer is between an upper surface of the contact filling layer and a lower surface of the contact filling layer, and outer walls of the contact barrier layer and outer walls of the contact filling layer extend along a common plane.

This application claims priority from Korean Patent Application No. 10-2023-0071614, filed on Jun. 2, 2023, in the Korean Intellectual Property Office, the disclosure of which is incorporated by reference herein in its entirety.

### BACKGROUND

### 1. Field

The present disclosure relates to a semiconductor device.

### 2. Description of Related Art

As one of the scaling techniques for increasing the density of a semiconductor device, a multi-gate transistor has been suggested. The multi-gate transistor is obtained by forming a fin- or nanowire-shaped multi-channel active pattern (or silicon body) on a substrate and forming gates on a surface of the multi-channel active pattern.

As the pitch size of a semiconductor device decreases, research needs to be conducted to reduce capacitance and secure electrical stability between contacts in the semiconductor device.

### SUMMARY

One or more embodiments provide a semiconductor device with improved product reliability.

According to an aspect of an embodiment, a semiconductor device includes: an active pattern extending in a first direction; a gate structure including a gate electrode extending in a second direction and a gate spacer on the active pattern, wherein the gate electrode and the gate spacer are spaced apart from each other in the first direction; a source/drain pattern on the active pattern; a contact barrier layer on the source/drain pattern; and a contact filling layer on the contact barrier layer. An uppermost point of the contact barrier layer is between an upper surface of the contact filling layer and a lower surface of the contact filling layer, and outer walls of the contact barrier layer and outer walls of the contact filling layer extend along a common plane.

According to an aspect of an embodiment, a semiconductor device includes: an active pattern extending in a first direction; a gate structure including a gate electrode extending in a second direction and a gate spacer on the active pattern, wherein the gate electrode and the gate spacer are spaced apart from each other in the first direction; a source/drain pattern on the active pattern; a contact barrier layer on the source/drain pattern; and a contact filling layer on the contact barrier layer. The contact filling layer includes a first portion surrounded by the contact barrier layer and a second portion on the first portion that does not overlap the contact barrier layer in the first direction, and a first width along the first direction of the first portion is smaller than a second width along the first direction of the second portion, and outer walls of the contact barrier layer and outer walls of the second portion of the contact filling layer extend along a common plane.

According to an aspect of an embodiment, a semiconductor device includes: an active pattern extending in a first direction; a gate structure including a gate electrode extending in a second direction and a gate spacer on the active pattern, wherein the gate electrode and the gate spacer are spaced apart from each other in the first direction; a source/drain pattern on the active pattern; a silicide layer on the source/drain pattern; a contact barrier layer on the silicide layer; and a contact filling layer on the contact barrier layer. The contact filling layer includes a first portion surrounded by the contact barrier layer and a second portion on the first portion that does not overlap the contact barrier layer in the first direction. A first width of the first portion along the first direction is smaller than a second width of the second portion along the first direction. Outer walls of the contact barrier layer and outer walls of the second portion of the contact filling layer extend along a common plane. The contact barrier layer includes titanium nitride and the contact filling layer includes tungsten. An uppermost point of the contact barrier layer is between an upper surface of the gate electrode and a lower surface of the contact filling layer.

However, aspects of the present disclosure are not restricted to the one set forth herein. The above and other aspects of the present disclosure will become more apparent to one of ordinary skill in the art to which the present disclosure pertains by referencing the detailed description of the present disclosure given below.

### BRIEF DESCRIPTION OF DRAWINGS

The above and other objects, features and advantages will be more apparent from the following description of embodiments, taken in conjunction with the accompanying drawings, in which:

FIG. 1 is an example layout view of a semiconductor device according to embodiments.

FIG. 2 is an example cross-sectional view taken along line A-A of FIG. 1.

FIG. 3 is an enlarged view of portion P1 of FIG. 2.

FIG. 4 is an example cross-sectional view taken along line B-B of FIG. 1.

FIG. 5 is an example cross-sectional view taken along line C-C of FIG. 1.

FIG. 6 illustrates a semiconductor device according to embodiments.

FIG. 7 is an enlarged view of portion P2 of FIG. 6.

FIG. 8 illustrates a semiconductor device according to embodiments.

FIG. 9 is an enlarged view of portion P3 of FIG. 8.

FIG. 10 illustrates a semiconductor device according to embodiments.

FIG. 11 is an enlarged view of portion P4 of FIG. 10.

FIG. 12 illustrates a semiconductor device according to embodiments.

FIG. 13 illustrates a semiconductor device according to embodiments.

FIGS. 14 through 18 are views illustrating a semiconductor device according to embodiments.

FIGS. 19 through 27 are intermediate views for explaining a method of manufacturing a semiconductor device according to embodiments.

### DETAILED DESCRIPTION

Hereinafter, embodiments will be described with reference to the accompanying drawings. Embodiments described herein are example embodiments, and thus, the present disclosure is not limited thereto, and may be realized in various other forms. Each example embodiment provided in the following description is not excluded from being associated with one or more features of another example or another example embodiment also provided herein or not provided herein but consistent with the present disclosure. It will be understood that when an element or layer is referred to as being “on,” “connected to” or “coupled to” another element or layer, it can be directly on, connected or coupled to the other element or layer, or intervening elements or layers may be present. By contrast, when an element is referred to as being “directly on,” “directly connected to” or “directly coupled to” another element or layer, there are no intervening elements or layers present. As used herein, the term “and/or” includes any and all combinations of one or more of the associated listed items. Expressions such as “at least one of,” when preceding a list of elements, modify the entire list of elements and do not modify the individual elements of the list. For example, the expression, “at least one of a, b, and c,” should be understood as including only a, only b, only c, both a and b, both a and c, both b and c, or all of a, b, and c. It will be also understood that, even if a certain step or operation of manufacturing an apparatus or structure is described later than another step or operation, the step or operation may be performed later than the other step or operation unless the other step or operation is described as being performed after the step or operation. The same reference numerals are used for the same components in the drawings, and redundant descriptions thereof are omitted.

In the drawings relating to semiconductor devices according to embodiments, a fin field effect transistor (FinFET) including a fin pattern-shaped channel region, a transistor including a nanowire or nanosheet, a multi-bridge channel FET (MBCFET™), and a vertical FET are illustrated as examples. However, the present disclosure is not limited thereto. A semiconductor device according to embodiments may include a tunneling FET or a three-dimensional (3D) transistor. A semiconductor device according to embodiments may include a planar transistor. Further, the technical spirit of the present disclosure is applicable to two-dimensional (2D) material-based FETs and heterostructures thereof.

In addition, a semiconductor device according to embodiments may include a bipolar junction transistor, a lateral double diffused metal oxide semiconductor transistor (LDMOS), or the like.

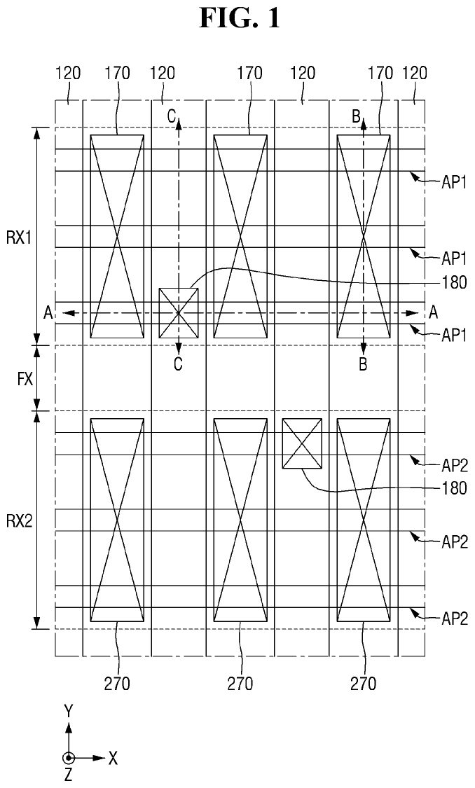

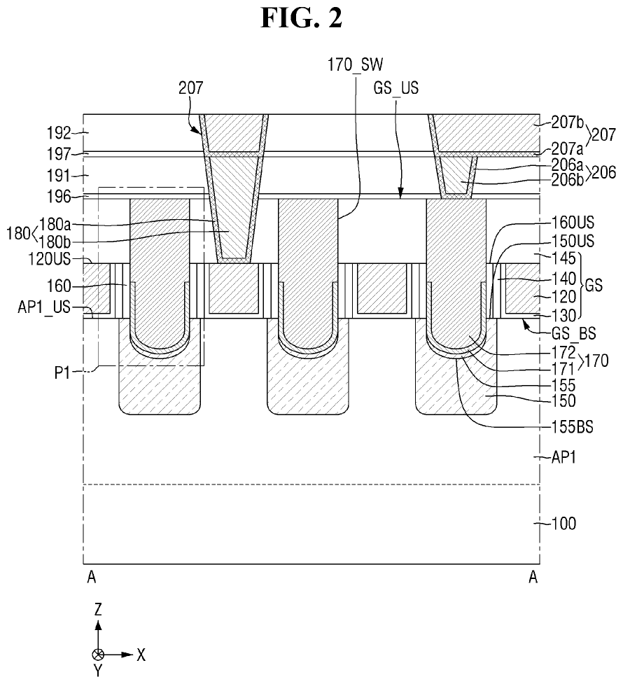

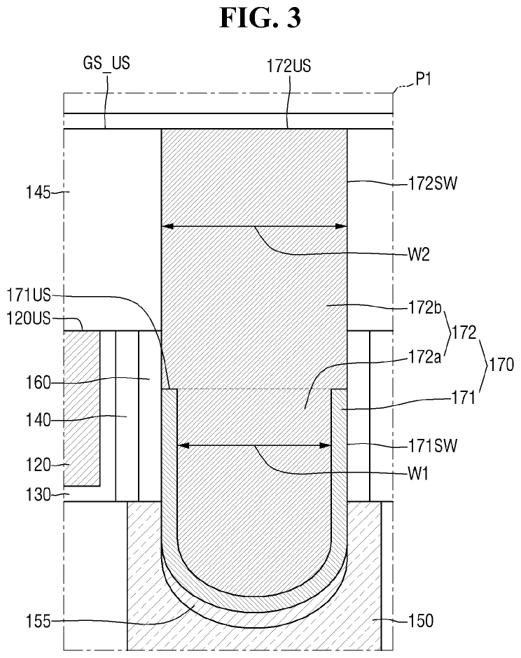

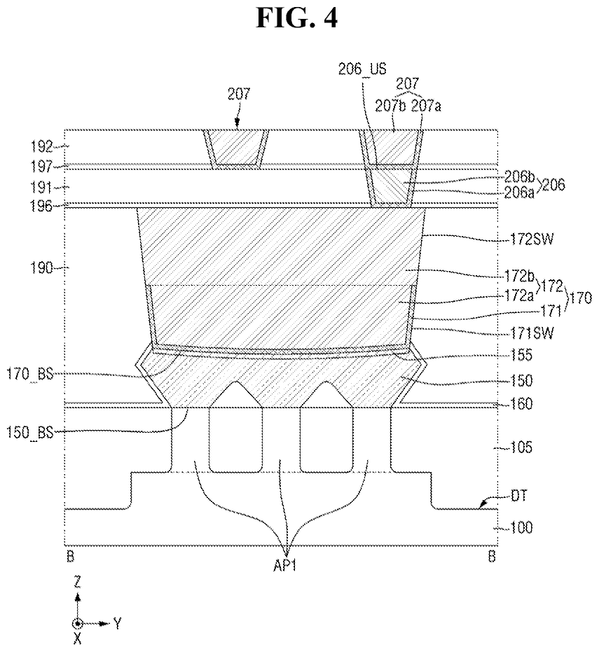

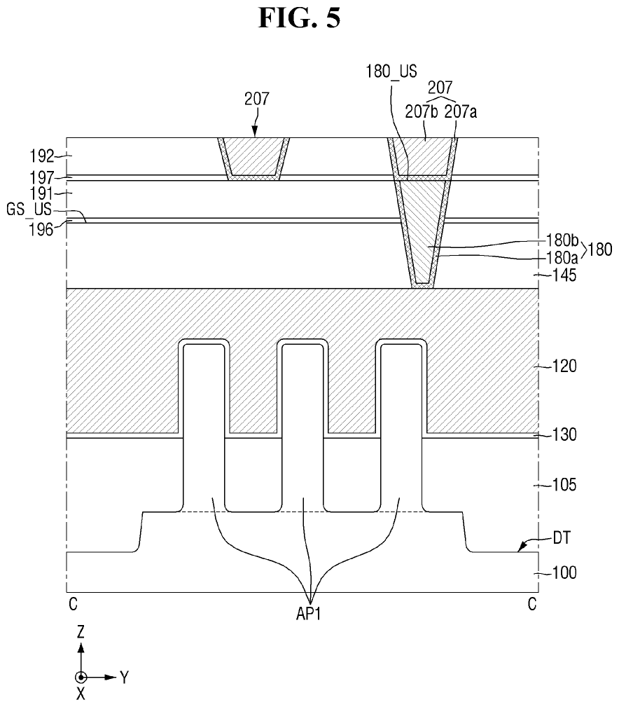

FIG. 1 is an example layout view of a semiconductor device according to embodiments. FIG. 2 is an example cross-sectional view taken along line A-A of FIG. 1. FIG. 3 is an enlarged view of portion P1 of FIG. 2. FIG. 4 is an example cross-sectional view taken along line B-B of FIG. 1. FIG. 5 is an example cross-sectional view taken along line C-C of FIG. 1.

Referring to FIGS. 1 through 5, the semiconductor device according to embodiments may include one or more first active patterns AP1, one or more second active patterns AP2, one or more first gate electrodes 120, first source/drain contacts 170, second source/drain contacts 270, and gate contacts 180.

A substrate 100 may include a first active area RX1, a second active area RX2, and a field area FX. The field area FX may be formed immediately adjacent to the first active area RX1 and the second active area RX2. The field area FX may form a boundary with the first active area RX1 and the second active area RX2.

The first active area RX1 and the second active area RX2 are spaced apart from each other. The first active area RX1 and the second active area RX2 may be separated by the field area FX.

In this regard, an element isolation layer may be disposed around the first active area RX1 and the second active area RX2 spaced apart from each other. Here, a part of the element isolation layer which is disposed between the first active area RX1 and the second active area RX2 may be the field area FX. For example, a part in which a channel region of a transistor, which may be an example of the semiconductor device, is formed may be an active area, and a part which divides the channel region of the transistor formed in the active area may be a field area. Alternatively, the active area may be a part in which a fin pattern or nanosheet used as a channel region of a transistor is formed, and the field area may be an area in which the fin pattern or nanosheet used as the channel region is not formed.

As illustrated in FIGS. 4 and 5, the field area FX may be defined by a deep trench DT, but the present disclosure is not limited thereto. In addition, it will be appreciated that those of ordinary skill in the art to which the present disclosure pertains can distinguish which part is a field area and which part is an active area.

For example, one of the first active area RX1 and the second active area RX2 may be a p type metal oxide semiconductor (PMOS) formation area, and the other may be an n type metal oxide semiconductor (NMOS) formation area. As another example, the first active area RX1 and the second active area RX2 may be PMOS formation areas. As another example, the first active area RX1 and the second active area RX2 may be NMOS formation areas.

The substrate 100 may be a silicon substrate or a silicon-on-insulator (SOI). The substrate 100 may include, but is not limited to, silicon germanium, silicon germanium on insulator (SGOI), indium antimonide, lead telluride, indium arsenide, indium phosphide, gallium arsenide, or gallium antimonide.

The first active patterns AP1 may be formed in the first active area RX1. The first active patterns AP1 may protrude from the substrate 100 in the first active area RX1. The first active patterns AP1 may extend on the substrate 100 along a first direction X. For example, each of the first active patterns AP1 may include long sides extending in the first direction X and short sides extending in a second direction Y. Here, the first direction X may cross the second direction Y and a third direction Z. In addition, the second direction Y may cross the third direction Z. The third direction Z may be a thickness direction of the substrate 100.

The second active patterns AP2 may be formed in the second active area RX2. The description of the second active patterns AP2 may be substantially the same as the description of the first active patterns AP1.

Each of the first active patterns AP1 and the second active patterns AP2 may be a multi-channel active pattern. In the semiconductor device according to embodiments, each of the first active patterns AP1 and the second active patterns AP2 may be, for example, a fin-shaped pattern. Each of the first active patterns AP1 and the second active patterns AP2 may be used as a channel region of a transistor. Although three first active patterns AP1 and three second active patterns AP2 are illustrated in the drawings, this is an example used for ease of description, and the present disclosure is not limited to this example. The number of the first active patterns AP1 and the number of the second active patterns AP2 may each be at least one.

Each of the first active patterns AP1 and the second active patterns AP2 may be a part of the substrate 100 or may include an epitaxial layer grown from the substrate 100. The first active patterns AP1 and the second active patterns AP2 may include, for example, silicon or germanium which is an elemental semiconductor material. In addition, the first active patterns AP1 and the second active patterns AP2 may include a compound semiconductor such as a group IV-IV compound semiconductor or a group III-V compound semiconductor.

The group IV-IV compound semiconductor may be, e.g., a binary or ternary compound including two or more of carbon (C), silicon (Si), germanium (Ge) and tin (Sn) or a compound obtained by doping the binary or ternary compound with a group IV element.

The group III-V compound semiconductor may be, e.g., a binary, ternary, or quaternary compound formed by bonding at least one of aluminum (Al), gallium (Ga) and indium (In) which are group III elements with one of phosphorus (P), arsenic (As) and antimony (Sb) which are group V elements.

In an example, the first active patterns AP1 and the second active patterns AP2 may include the same material. For example, each of the first active patterns AP1 and the second active patterns AP2 may be a silicon fin pattern. Alternatively, each of the first active patterns AP1 and the second active patterns AP2 may be a fin pattern including a silicon-germanium pattern. In another example, the first active patterns AP1 and the second active patterns AP2 may include different materials. For example, the first active patterns AP1 may be silicon fin patterns, and the second active patterns AP2 may be fin patterns including silicon-germanium patterns.

A field insulating layer 105 may be formed on the substrate 100. The field insulating layer 105 may be formed over the first active area RX1, the second active area RX2, and the field area FX. The field insulating layer 105 may fill the deep trench DT.

The field insulating layer 105 may cover sidewalls of the first active patterns AP1 and sidewalls of the second active patterns AP2. Each of the first active patterns AP1 and the second active patterns AP2 may protrude above an upper surface of the field insulating layer 105. The field insulating layer 105 may include, for example, an oxide layer, a nitride layer, an oxynitride layer, or a combination thereof.

One or more gate structures GS may be disposed on the substrate 100. For example, the gate structures GS may be disposed on the field insulating layer 105. The gate structures GS may extend in the second direction Y. Adjacent gate structures GS may be spaced apart from each other in the first direction X.

The gate structure GS may be disposed on the first active patterns AP1 and the second active patterns AP2. The gate structures GS may cross the first active patterns AP1 and the second active patterns AP2.

Although the gate structures GS are disposed across the first active area RX1 and the second active area RX2 in the drawings, this is an example used for ease of description, and the present disclosure is not limited to this example. For example, some of the gate structures GS may be divided into two parts by a gate separation structure disposed on the field insulating layer 105 and may be disposed accordingly in the first active area RX1 and the second active area RX2.

Each of the gate structures GS may include, for example, a gate electrode 120, a gate insulating layer 130, gate spacers 140, and a gate capping layer 145.

The gate electrode 120 may be disposed on the first active patterns AP1 and the second active patterns AP2. The gate electrode 120 may cross the first active patterns AP1 and the second active patterns AP2. The gate electrode 120 may cover the first active patterns AP1 and the second active patterns AP2 protruding above the upper surface of the field insulating layer 105. The gate electrode 120 may include long sides extending in the second direction Y and short sides extending in the first direction X.

An upper surface of the gate electrode 120 may be a flat surface. However, the present disclosure is not limited thereto. For example, the upper surface of the gate electrode 120 may be a concave surface recessed toward upper surfaces of the first active patterns AP1.

The gate electrode 120 may include at least one of, for example, titanium nitride (TiN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAlN), tantalum aluminum nitride (TaAlN), tungsten nitride (WN), ruthenium (Ru), titanium aluminum (TiAl), titanium aluminum carbonitride (TiAlC—N), titanium aluminum carbide (TiAlC), titanium carbide (TIC), tantalum carbonitride (TaCN), tungsten (W), aluminum (Al), copper (Cu), cobalt (Co), titanium (Ti), tantalum (Ta), nickel (Ni), platinum (Pt), nickel platinum (Ni—Pt), niobium (Nb), niobium nitride (NbN), niobium carbide (NbC), molybdenum (Mo), molybdenum nitride (MoN), molybdenum carbide (MoC), tungsten carbide (WC), rhodium (Rh), palladium (Pd), iridium (Ir), osmium (Os), silver (Ag), gold (Au), zinc (Zn), vanadium (V), and combinations thereof.

The gate electrode 120 may include a conductive metal oxide, a conductive metal oxynitride, or an oxidized form of any one of the above materials.

The gate electrodes 120 may be disposed on both sides of each source/drain pattern 150 to be described later. The gate structures GS may be disposed on both sides of each source/drain pattern 150 in the first direction X.

For example, all of the gate electrodes 120 disposed on both sides of each source/drain pattern 150 may be normal gate electrodes used as gates of a transistor. As another example, a gate electrode 120 disposed on one side of each source/drain pattern 150 may be used as a gate of a transistor, but a gate electrode 120 disposed on the other side of each source/drain pattern 150 may be a dummy gate electrode.

The gate spacers 140 may be disposed on sidewalls of the gate electrode 120. The gate spacers 140 may extend in the second direction Y. The gate spacers 140 may include at least one of, for example, silicon nitride (SiN), silicon oxynitride (SiON), silicon oxide (SiO₂), silicon oxycarbonitride (SiOCN), silicon boron nitride (SiBN), silicon oxyboron nitride (SiOBN), silicon oxycarbide (SiOC), and combinations thereof.

The gate insulating layer 130 may extend along the sidewalls and bottom surface of the gate electrode 120. The gate insulating layer 130 may be formed on the first active patterns AP1, the second active patterns AP2, and the field insulating layer 105. The gate insulating layer 130 may be formed between the gate electrode 120 and the gate spacers 140.

The gate insulating layer 130 may be formed along the profile of the first active patterns AP1 protruding above the field insulating layer 105 and along the upper surface of the field insulating layer 105. The first gate insulating layer 130 may be formed along the profile of the second active patterns AP2 protruding above the field insulating layer 105.

The gate insulating layer 130 may include silicon oxide, silicon oxynitride, silicon nitride, or a high-k material having a higher dielectric constant than silicon oxide. The high-k material may include one or more of, for example, boron nitride, hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate.

Although the gate insulating layer 130 is illustrated as a single layer, this is an example used for ease of description, and the present disclosure is not limited to this example. The gate insulating layer 130 may include a plurality of layers. The gate insulating layer 130 may include an interfacial layer disposed between the first active patterns AP1 and the gate electrode 120 and between the second active patterns AP2 and the gate electrode 120 and a high-k insulating layer. For example, the interfacial layer may be formed along the profile of the first active patterns AP1 and the profile of the second active patterns AP2 protruding above the field insulating layer 105.

The semiconductor device according to embodiments may include a negative capacitance FET including a negative capacitor. For example, the gate insulating layer 130 may include a ferroelectric material layer having ferroelectric properties and a paraelectric material layer having paraelectric properties.

The ferroelectric material layer may have a negative capacitance, and the paraelectric material layer may have a positive capacitance. For example, when two or more capacitors are connected in series and the capacitance of each of the capacitors has a positive value, the total capacitance is reduced compared with the capacitance of each individual capacitor. On the other hand, when at least one of the capacitances of two or more capacitors connected in series has a negative value, the total capacitance may have a positive value and may be greater than an absolute value of each individual capacitance.

When the ferroelectric material layer having a negative capacitance and the paraelectric material layer having a positive capacitance are connected in series, the total capacitance value of the ferroelectric material layer and the paraelectric material layer connected in series may increase. By using the increase in the total capacitance value, a transistor including the ferroelectric material layer may have a sub-threshold swing (SS) of less than 60 mV/decade at room temperature.

The ferroelectric material layer may have ferroelectric properties. The ferroelectric material layer may include at least one of, e.g., hafnium oxide, hafnium zirconium oxide, barium strontium titanium oxide, barium titanium oxide, and lead zirconium titanium oxide. Here, for example, hafnium zirconium oxide may be a material obtained by doping hafnium oxide with zirconium (Zr). As another example, hafnium zirconium oxide may be a compound of hafnium (Hf), zirconium (Zr), and oxygen (O).

The ferroelectric material layer may further include a doped dopant. For example, the dopant may include at least one of aluminum (Al), titanium (Ti), niobium (Nb), lanthanum (La), yttrium (Y), magnesium (Mg), silicon (Si), calcium (Ca), cerium (Ce), dysprosium (Dy), erbium (Er), gadolinium (Gd), germanium (Ge), scandium (Sc), strontium (Sr), and tin (Sn). The type of dopant included in the ferroelectric material layer may vary according to which ferroelectric material is included in the ferroelectric material layer.

When the ferroelectric material layer includes hafnium oxide, the dopant included in the ferroelectric material layer may include at least one of, e.g., gadolinium (Gd), silicon (Si), zirconium (Zr), aluminum (Al), and yttrium (Y).

When the dopant is aluminum (Al), the ferroelectric material layer may include 3 to 8 atomic % (at %) of aluminum. Here, the ratio of the dopant may be the ratio of aluminum to the sum of hafnium and aluminum.

When the dopant is silicon (Si), the ferroelectric material layer may include 2 to 10 at % of silicon. When the dopant is yttrium (Y), the ferroelectric material layer may include 2 to 10 at % of yttrium. When the dopant is gadolinium (Gd), the ferroelectric material layer may include 1 to 7 at % of gadolinium. When the dopant is zirconium (Zr), the ferroelectric material layer may include 50 to 80 at % of zirconium.

The paraelectric material layer may have paraelectric properties. The paraelectric material layer may include at least one of, e.g., silicon oxide and a metal oxide having a high dielectric constant. The metal oxide included in the paraelectric material layer may include, but is not limited to, at least one of, e.g., hafnium oxide, zirconium oxide, and aluminum oxide.

The ferroelectric material layer and the paraelectric material layer may include the same material. While the ferroelectric material layer has ferroelectric properties, the paraelectric material layer may not have ferroelectric properties. For example, when the ferroelectric material layer and the paraelectric material layer include hafnium oxide, the crystal structure of hafnium oxide included in the ferroelectric material layer is different from the crystal structure of hafnium oxide included in the paraelectric material layer.

The ferroelectric material layer may have a thickness having ferroelectric properties. The thickness of the ferroelectric material layer may be, but is not limited to, 0.5 to 10 nm. Each ferroelectric material may have a different critical thickness showing ferroelectric properties. Therefore, the thickness of the ferroelectric material layer may vary according to the ferroelectric material.

For example, the gate insulating layer 130 may include one ferroelectric material layer. As another example, the gate insulating layer 130 may include a plurality of ferroelectric material layers spaced apart from each other. The gate insulating layer 130 may have a structure in which a plurality of ferroelectric material layers and a plurality of paraelectric material layers are alternately stacked.

The gate capping layer 145 may be disposed on the upper surface of the gate electrode 120 and upper surfaces of the gate spacers 140. The gate capping layer 145 may be disposed on a source/drain etch stop layer 160. The gate capping layer 145 may cover an upper surface 160US of the source/drain etch stop layer 160.

An upper surface of the gate capping layer 145 may be an upper surface GS_US of each of the gate structures GS. A lower surface of the gate capping layer 145 may be flat. An upper surface 120US of the gate electrode 120 may be flat.

The gate capping layer 145 may include at least one of, for example, silicon nitride (SiN), silicon oxynitride (SiON), silicon oxide (SiO₂), silicon carbonitride (SiCN), silicon oxycarbonitride (SiOCN), and combinations thereof.

The gate capping layer 145 may also be disposed between the gate spacers 140. For example, the upper surface of the gate capping layer 145 may lie in the same plane as the upper surfaces of the gate spacers 140. In this case, the upper surface GS_US of each of the gate structures GS may include the upper surface of the gate capping layer 145 and the upper surfaces of the gate spacers 140.

The source/drain patterns 150 may be located on the substrate 100. The source/drain patterns 150 may be formed on the first active patterns AP1. The source/drain patterns 150 are connected to the first active patterns AP1. Bottom surfaces 150_BS of the first source/drain patterns 150 contact the first active patterns AP1.

The source/drain patterns 150 may be disposed on side surfaces of each of the gate structures GS. Each of the source/drain patterns 150 may be disposed between the gate structures GS.

For example, the source/drain patterns 150 may be disposed on both sides of each of the gate structures GS. A source/drain pattern 150 may be disposed on a side of each of the gate structures GS but may not be disposed on the other side of the gate structure GS.

The source/drain patterns 150 may include epitaxial patterns. The source/drain patterns 150 may include a semiconductor material. Each of the source/drain patterns 150 may be included in a source/drain region of a transistor that uses the first active patterns AP1 as a channel region.

Each of the source/drain patterns 150 may be connected to a channel region used as channels of the first active patterns AP1. Although each of the source/drain patterns 150 is illustrated as a structure into which three epitaxial patterns respectively formed on the first active patterns AP1 have merged, this is an example used for ease of description, and the present disclosure is not limited to this example. For example, the epitaxial patterns respectively formed on the first active patterns AP1 may also be separated from each other.

For example, an air gap may be disposed in a space between portions of each source/drain pattern 150 merged with the field insulating layer 105. As another example, an insulating material may fill the space between the portions of each source/drain pattern 150 merged with the field insulating layer 105.

The same source/drain patterns as those described above may be disposed on the second active patterns AP2 between the gate structures GS.

The source/drain etch stop layer 160 may extend along the upper surface of the field insulating layer 105, sidewalls of each gate structure GS, and the profile of each source/drain pattern 150. The source/drain etch stop layer 160 may be disposed on an upper surface of each source/drain pattern 150 and sidewalls of each source/drain pattern 150.

The source/drain etch stop layer 160 may include a material having an etch selectivity with respect to a first interlayer insulating layer 190 to be described later. The source/drain etch stop layer 160 may include at least one of, for example, silicon nitride (SiN), silicon oxynitride (SiON), silicon oxycarbonitride (SiOCN), silicon boron nitride (SiBN), silicon oxyboron nitride (SiOBN), silicon oxycarbide (SiOC), and combinations thereof.

The first interlayer insulating layer 190 is disposed on the source/drain etch stop layer 160. The first interlayer insulating layer 190 may be formed on the field insulating layer 105. The first interlayer insulating layer 190 may be disposed on the source/drain patterns 150. The first interlayer insulating layer 190 may be disposed between the source/drain etch stop layer 160 and a source/drain contact barrier layer 171.

The first interlayer insulating layer 190 may not cover the upper surfaces GS_US of the gate structures GS. For example, an upper surface of the first interlayer insulating layer 190 may lie in the same plane as the upper surfaces GS_US of the gate structures GS.

The first interlayer insulating layer 190 may include at least one of, for example, silicon oxide, silicon nitride, silicon oxynitride, and a low-k material. The low-k material may include, but is not limited to, for example, fluorinated tetraethylorthosilicate (FTEOS), hydrogen silsesquioxane (HSQ), bis-benzocyclobutene (BCB), tetramethylorthosilicate (TMOS), octamethyleyclotetrasiloxane (OMCTS), hexamethyldisiloxane (HMDS), trimethylsilyl borate (TMSB), diacetoxyditertiarybutosiloxane (DADBS), trimethylsilil phosphate (TMSP), polytetrafluoroethylene (PTFE), tonen silazen (TOSZ), fluoride silicate glass (FSG), polyimide nanofoams such as polypropylene oxide, carbon doped silicon oxide (CDO), organo silicate glass (OSG), SiLK, amorphous fluorinated carbon, silica aerogels, silica xerogels, mesoporous silica, or a combination of the same.

The first source/drain contacts 170 may be disposed in the first active area RX1. The second source/drain contacts 270 may be disposed in the second active area RX2. The first source/drain contacts 170 may be connected to the source/drain patterns 150 formed in the first active area RX1. The second source/drain contacts 270 may be connected to source/drain patterns formed in the second active area RX2.

Some of the first source/drain contacts 170 may be directly connected to some of the second source/drain contacts 270. For example, in the semiconductor device according to embodiments, at least one source/drain contact may be disposed over the first active area RX1 and the second active area RX2.

Because the details of the second source/drain contacts 270 are substantially the same as the details of the first source/drain contacts 170, the following description will be based on the first source/drain contacts 170 on the first active patterns AP1.

The gate contacts 180 may be disposed on the gate structures GS. Each of the gate contacts 180 may be connected to the gate electrode 120 included in a gate structure GS.

Each of the gate contacts 180 may be disposed at a position overlapping a gate structure GS. In the semiconductor device according to embodiments, at least a portion of each of the gate contacts 180 may be disposed at a position overlapping at least one of the first active area RX1 and the second active area RX2. For example, in plan view, the whole of each of the gate contacts 180 may be disposed at a position overlapping the first active area RX1 or the second active area RX2.

Each of the first source/drain contacts 170 may pass through the source/drain etch stop layer 160 and may be connected to a source/drain pattern 150. Each of the first source/drain contacts 170 may be disposed on the source/drain pattern 150.

The first source/drain contacts 170 may be disposed in the first interlayer insulating layer 190. The first source/drain contacts 170 may be surrounded by the first interlayer insulating layer 190.

A contact silicide layer 155 may be disposed between each first source/drain contact 170 and each source/drain pattern 150. Although the contact silicide layer 155 is illustrated as being formed along the profile of a boundary surface between each source/drain pattern 150 and each first source/drain contact 170, the present disclosure is not limited thereto. A lower surface 155BS of the contact silicide layer 155 may be disposed below an upper surface 150US of each source/drain pattern 150. The contact silicide layer 155 may include, for example, a metal silicide material.

The first interlayer insulating layer 190 does not cover upper surfaces of the first source/drain contacts 170. For example, the upper surfaces of the first source/drain contacts 170 may not protrude above the upper surfaces GS_US of the gate structures GS. The upper surfaces of the first source/drain contacts 170 may lie in the same plane as the upper surfaces GS_US of the gate structures GS. As another example, the upper surfaces of the first source/drain contacts 170 may protrude above the upper surfaces GS_US of the gate structures GS.

Each of the first source/drain contacts 170 may include a source/drain contact barrier layer 171 and a source/drain contact filling layer 172 on the source/drain contact barrier layer 171. The source/drain contact barrier layer 171 may extend along sidewalls and a bottom surface of the source/drain contact filling layer 172.

The source/drain contact barrier layer 171 may be disposed on the contact silicide layer 155. The source/drain contact barrier layer 171 may be disposed between the contact silicide layer 155 and the source/drain contact filling layer 172. The source/drain contact filling layer 172 may not contact the contact silicide layer 155. The source/drain contact filling layer 172 may be spaced apart from the contact silicide layer 155 with the source/drain contact barrier layer 171 interposed between them.

The source/drain contact barrier layer 171 may surround a portion of the source/drain contact filling layer 172. For example, the source/drain contact barrier layer 171 may surround only a first portion 172a of the source/drain contact filling layer 172. The source/drain contact barrier layer 171 may not surround a second portion 172b of the source/drain contact filling layer 172. For example, the source/drain contact barrier layer 171 may be disposed on sidewalls of the first portion 172a of the source/drain contact filling layer 172 and may not be disposed on sidewalls of the second portion 172b. The source/drain contact barrier layer 171 may have a U shape. The source/drain contact barrier layer 171 may surround the entire lower surface of the source/drain contact filling layer 172.

The source/drain contact filling layer 172 may include the first portion 172a and the second portion 172b. The second portion 172b may be disposed on the first portion 172a. The second portion 172b may cover the first portion 172a. The first portion 172a may be completely overlapped by the second portion 172b.

The first portion 172a may be surrounded by the source/drain contact barrier layer 171. The sidewalls and lower surface of the first portion 172a may be surrounded by the source/drain contact barrier layer 171. The first portion 172a may overlap the source/drain contact barrier layer 171 in the first direction X and the second direction Y.

The second portion 172b may not be surrounded by the source/drain contact barrier layer 171. The second portion 172b may be disposed on the source/drain contact barrier layer 171. The second portion 172b may not overlap the source/drain contact barrier layer 171 in the first direction X and the second direction Y. The second portion 172b may overlap the source/drain contact barrier layer 171 in the third direction Z.

The first portion 172a may have a first width W1 along the first direction X. The first width W1 of the first portion 172a may refer to a distance between the sidewalls of the first portion 172a which contact inner walls of the source/drain contact barrier layer 171. The second portion 172b may have a second width W2 along the first direction X. The second width W2 of the second portion 172b may refer to a distance between outer walls 172SW of the source/drain contact filling layer 172. The outer walls 172SW of the source/drain contact filling layer 172 may correspond to outer walls of the second portion 172b.

The first width W1 of the first portion 172a may be smaller than the second width W2 of the second portion 172b. Accordingly, the source/drain contact filling layer 172 may have a step between the first portion 172a and the second portion 172b having different widths.

A grain size of the first portion 172a may be smaller than a grain size of the second portion 172b. For example, the grain size of the first portion 172a of the source/drain contact filling layer 172 which is surrounded by the source/drain contact barrier layer 171 including titanium nitride may be relatively smaller than the grain size of the second portion 172b of the source/drain contact filling layer 172 which is not surrounded by the source/drain contact barrier layer 171.

The outer walls 172SW of the source/drain contact filling layer 172 and outer walls 171SW of the source/drain contact barrier layer 171 may lie in the same plane. For example, the outer walls 172SW of the source/drain contact filling layer 172 and the outer walls 171SW of the source/drain contact barrier layer 171 may extend in the same plane to overlap each other along the third direction Z.

An uppermost point 171US of the source/drain contact barrier layer 171 may be disposed below an upper surface 172US of the source/drain contact filling layer 172 based on an upper surface AP1_US of an active pattern. The uppermost point 171US of the source/drain contact barrier layer 171 may be disposed below the upper surface 120US of the gate electrode 120 based on the upper surface AP1_US of the active pattern. Accordingly, a portion of the second portion 172b of the source/drain contact filling layer 172 may contact the source/drain etch stop layer 160.

The source/drain contact barrier layer 171 may not contact the gate capping layer 145. The source/drain contact barrier layer 171 may be disposed between portions of the source/drain etch stop layer 160 in the first direction X.

The first portion 172a of the source/drain contact filling layer 172 may not contact the gate capping layer 145. The second portion 172b of the source/drain contact filling layer 172 may contact the gate capping layer 145. The upper surface 172US of the source/drain contact filling layer 172 may lie in the same plane as the upper surfaces GS_US of the gate structures GS.

The first portion 172a of the source/drain contact filling layer 172 may not contact the first interlayer insulating layer 190. The first portion 172a of the source/drain contact filling layer 172 may not contact the first interlayer insulating layer 190 because it is surrounded by the source/drain contact barrier layer 171. The second portion 172b of the source/drain contact filling layer 172 may contact the first interlayer insulating layer 190.

Although a bottom surface 170_BS of each source/drain contact 170 is illustrated as having a flat shape, the present disclosure is not limited thereto. For example, the bottom surface 170_BS of each source/drain contact 170 may have a wavy shape. The bottom surface 170_BS of each source/drain contact 170 may contact the contact silicide layer 155.

The source/drain contact barrier layer 171 may include at least one of, for example, tantalum (Ta), tantalum nitride (TaN), titanium (Ti), titanium nitride (TiN), titanium silicon nitride (TiSiN), ruthenium (Ru), cobalt (Co), nickel (Ni), nickel boron (NiB), tungsten (W), tungsten nitride (WN), tungsten carbonitride (WCN), zirconium (Zr), zirconium nitride (ZrN), vanadium (V), vanadium nitride (VN), niobium (Nb), niobium nitride (NbN), platinum (Pt), iridium (Ir), rhodium (Rh), and a 2D material. In the semiconductor device according to embodiments, the 2D material may be a metallic material and/or a semiconductor material. The 2D material may include a 2D allotrope or a 2D compound, for example, may include, but is not limited to, at least one of graphene, molybdenum disulfide (MoS₂), molybdenum diselenide (MoSe₂), tungsten diselenide (WSe₂), and tungsten disulfide (WS₂). That is, the above 2D materials are listed as examples, and a 2D material that can be included in the semiconductor device of the present disclosure is not limited to the above materials.

The source/drain contact barrier layer 171 may not include silicon (Si) and boron (B).

The source/drain contact filling layer 172 may include at least one of, for example, aluminum (Al), tungsten (W), cobalt (Co), ruthenium (Ru), silver (Ag), gold (Au), manganese (Mn), and molybdenum (Mo).

Each of the gate contacts 180 may include a gate barrier layer 180a and a gate filling layer 180b on the gate barrier layer 180a. The description of materials included in the gate barrier layer 180a and the gate filling layer 180b may be the same as the description of the materials included in the source/drain barrier layer 171 and the source/drain filling layer 172.

Each of the gate contacts 180 may be disposed on a gate electrode 120. Each of the gate contacts 180 may pass through the gate capping layer 145 and may be connected to the gate electrode 120. Each of the gate contacts 180 may pass through a first etch stop layer 196 and a second interlayer insulating layer 191.

The first etch stop layer 196 may be disposed on the first interlayer insulating layer 190, the gate structures GS, the source/drain contacts 170, and the gate contacts 180. The second interlayer insulating layer 191 is disposed on the first etch stop layer 196.

The first etch stop layer 196 may include a material having an etch selectivity with respect to the second interlayer insulating layer 191. The first etch stop layer 196 may include at least one of, for example, silicon nitride (SiN), silicon oxynitride (SION), silicon oxycarbonitride (SiOCN), silicon boron nitride (SiBN), silicon oxyboron nitride (SiOBN), silicon oxycarbide (SiOC), aluminum oxide (AlO), aluminum nitride (AlN), aluminum oxycarbide (AlOC), and combinations thereof. Although the first etch stop layer 196 is illustrated as a single layer, the present disclosure is not limited thereto. In some embodiments, the first etch stop layer 196 may not be formed. The second interlayer insulating layer 191 may include at least one of, for example, silicon oxide, silicon nitride, silicon carbonitride, silicon oxynitride, and a low-k material.

A via plug 206 may be disposed in the second interlayer insulating layer 191. The via plug 206 may pass through the first etch stop layer 196 and may be directly connected to a first source/drain contact 170 and a gate contact 180.

The via plug 206 may include a via barrier layer 206a and a via filling layer 206b. The via barrier layer 206a may extend along sidewalls and a bottom surface of the via filling layer 206b. The via barrier layer 206a may include at least one of, for example, tantalum (Ta), tantalum nitride (TaN), titanium (Ti), titanium nitride (TiN), titanium silicon nitride (TiSiN), nickel (Ni), nickel boron (NiB), tungsten nitride (WN), tungsten carbonitride (WCN), zirconium (Zr), zirconium nitride (ZrN), vanadium (V), vanadium nitride (VN), niobium (Nb), niobium nitride (NbN), platinum (Pt), iridium (Ir), rhodium (Rh), and a 2D material. The via filling layer 206b may include at least one of, for example, aluminum (Al), tungsten (W), cobalt (Co), ruthenium (Ru), copper (Cu), silver (Ag), gold (Au), manganese (Mn), and molybdenum (Mo).

A second etch stop layer 197 may be disposed between the second interlayer insulating layer 191 and a third interlayer insulating layer 192. The second etch stop layer 197 may extend along an upper surface of the second interlayer insulating layer 191.

The second etch stop layer 197 may include a material having an etch selectivity with respect to the third interlayer insulating layer 192. The description of materials included in the second etch stop layer 197 may be the same as the description of the materials included in the first etch stop layer 196. Although the second etch stop layer 197 is illustrated as a single layer, the present disclosure is not limited thereto. In some embodiments, the second etch stop layer 197 may not be formed. The third interlayer insulating layer 192 may include at least one of, for example, silicon oxide, silicon nitride, silicon carbonitride, silicon oxynitride, and a low-k material.

Wiring lines 207 may be disposed in the third interlayer insulating layer 192. One of the wiring lines 207 is connected to the via plug 206. One of the wiring lines 207 may contact the via plug 206.

Each of the wiring lines 207 may include a wiring barrier layer 207a and a wiring filling layer 207b. The wiring barrier layer 207a may include at least one of, for example, tantalum (Ta), tantalum nitride (TaN), titanium (Ti), titanium nitride (TiN), titanium silicon nitride (TiSiN), ruthenium (Ru), cobalt (Co), nickel (Ni), nickel boron (NiB), tungsten (W), tungsten nitride (WN), tungsten carbonitride (WCN), zirconium (Zr), zirconium nitride (ZrN), vanadium (V), vanadium nitride (VN), niobium (Nb), niobium nitride (NbN), platinum (Pt), iridium (Ir), rhodium (Rh), and a 2D material. The wiring filling layer 207b may include at least one of, for example, aluminum (Al), copper (Cu), tungsten (W), cobalt (Co), ruthenium (Ru), silver (Ag), gold (Au), manganese (Mn), and molybdenum (Mo).

The wiring barrier layer 207a may also not be disposed between the via filling layer 206b and the wiring filling layer 207b. A first connection contact connecting the via plug 206 and a first source/drain contact 170 may be further disposed between the via plug 206 and the first source/drain contact 170. In addition, a second connection contact connecting a wiring line 207 and a gate contact 180 may be further disposed between the wiring line 207 and the gate contact 180.

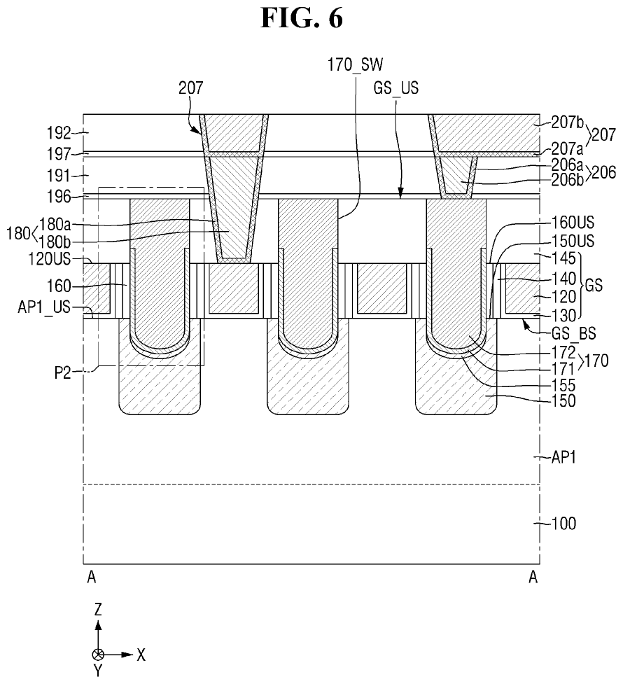

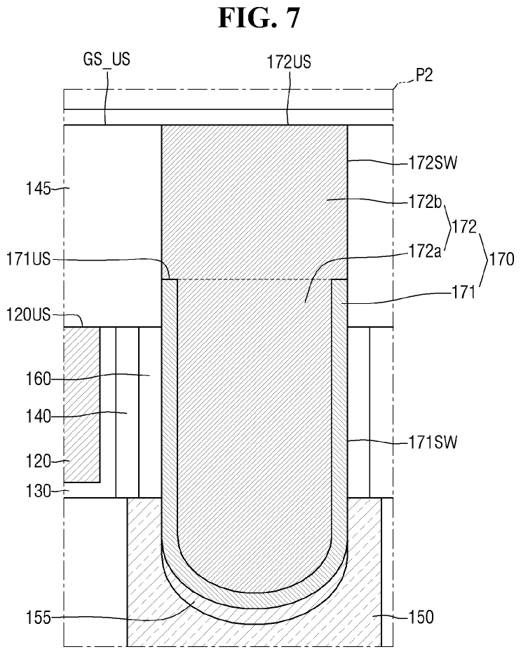

FIG. 6 illustrates a semiconductor device according to embodiments. FIG. 7 is an enlarged view of portion P2 of FIG. 6. For ease of description, the following description will focus on differences from the semiconductor device described above with reference to FIGS. 1 through 5.

Referring to FIGS. 6 and 7, an uppermost point 171US of a source/drain contact barrier layer 171 may be disposed above an upper surface 120US of each gate electrode based on an upper surface AP1_US of an active pattern. The uppermost point 171US of the source/drain contact barrier layer 171 may be disposed below an upper surface 172US of a source/drain contact filling layer 172 based on the upper surface AP1_US of the active pattern. A portion of the source/drain contact barrier layer 171 may contact a gate capping layer 145.

A second portion 172b of the source/drain contact filling layer 172 may not contact a source/drain etch stop layer 160.

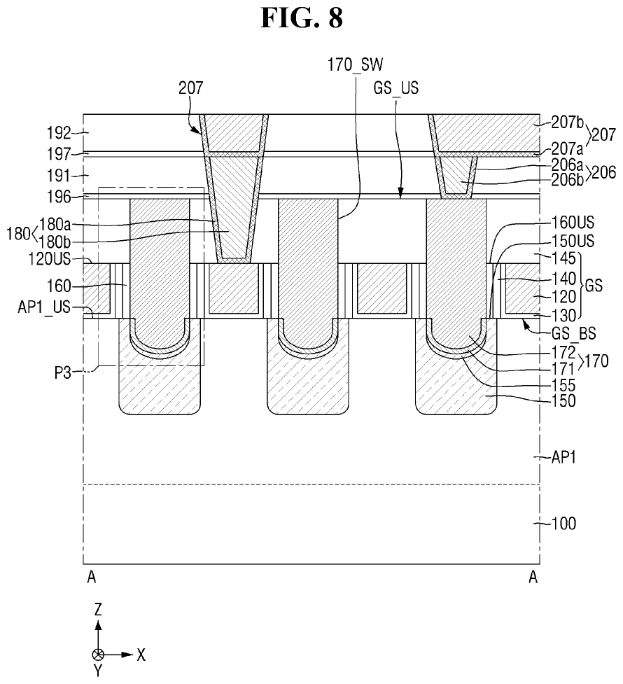

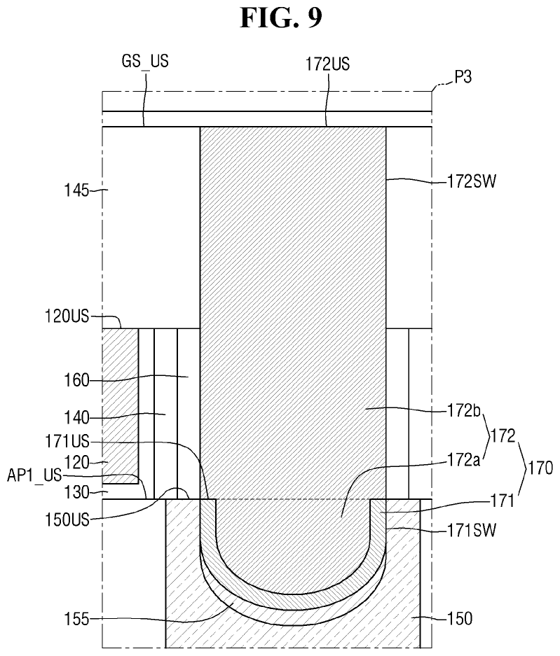

FIG. 8 illustrates a semiconductor device according to embodiments. FIG. 9 is an enlarged view of portion P3 of FIG. 8. For ease of description, the following description will focus on differences from the semiconductor device described above with reference to FIGS. 1 through 5.

Referring to FIGS. 8 and 9, an uppermost point 171US of a source/drain contact barrier layer may lie in the same plane as an upper surface AP1_US of an active pattern. The uppermost point 171US of the source/drain contact barrier layer may also be disposed below the upper surface AP1_US of the active pattern. The uppermost point 171US of the source/drain contact barrier layer may lie in the same plane as an upper surface 150US of each source/drain pattern. The uppermost point 171US of the source/drain contact barrier layer may also be disposed below the upper surface 150US of each source/drain pattern.

A first portion 172a of a source/drain contact filling layer 172 may not overlap a gate electrode 120 in the first direction X. The first portion 172a of the source/drain contact filling layer 172 may be disposed below the upper surface 150US of each source/drain pattern. A second portion 172b of the source/drain contact filling layer 172 may be disposed above the upper surface 150US of each source/drain pattern. The second portion 172b of the source/drain contact filling layer 172 may contact a source/drain etch stop layer 160 and a gate capping layer 145. The second portion 172b of the source/drain contact filling layer 172 may extend along the source/drain etch stop layer 160 and the gate capping layer 145.

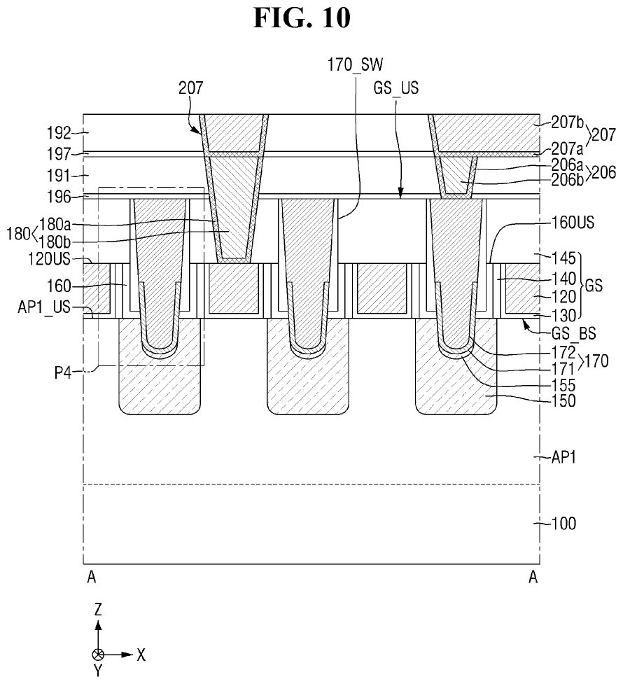

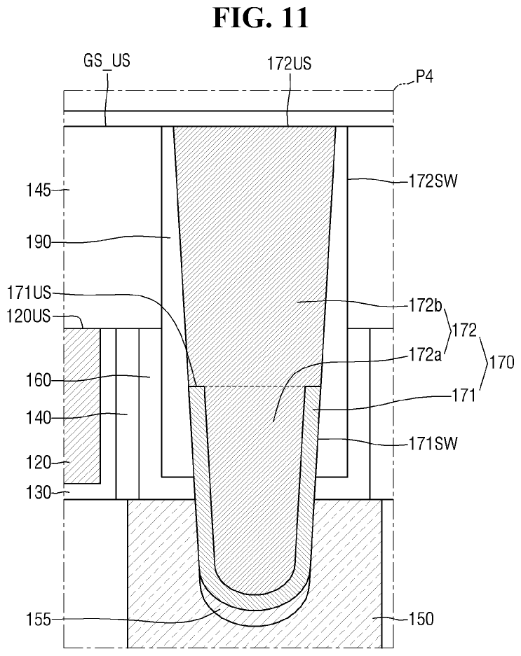

FIG. 10 illustrates a semiconductor device according to embodiments. FIG. 11 is an enlarged view of portion P4 of FIG. 10. For ease of description, the following description will focus on differences from the semiconductor devices described above with reference to FIGS. 1 through 9.

Referring to FIGS. 10 and 11, a width of each first source/drain contact 170 may increase as a distance from an upper surface AP1_US of an active pattern increases. For example, sidewalls of each first source/drain contact 170 may be inclined, in contrast to extending perpendicular to the upper surface AP1_US of the active pattern.

Each of the first source/drain contacts 170 may be disposed in a first interlayer insulating layer 190 between portions of a gate capping layer 145. Each of the first source/drain contacts 170 may be surrounded by the first interlayer insulating layer 190. A source/drain contact filling layer 172 may not contact the gate capping layer 145.

In a cross-sectional view taken along the first direction X, a second portion 172b of the source/drain contact filling layer 172 may contact the first interlayer insulating layer 190. In the cross-sectional view taken along the first direction X, a first portion 172a of the source/drain contact filling layer 172 may not contact the first interlayer insulating layer 190. In the cross-sectional view taken along the first direction X, a source/drain contact barrier layer 171 may contact the first interlayer insulating layer 190 and a source/drain etch stop layer 160. The source/drain contact barrier layer 171 may pass through the source/drain etch stop layer 160.

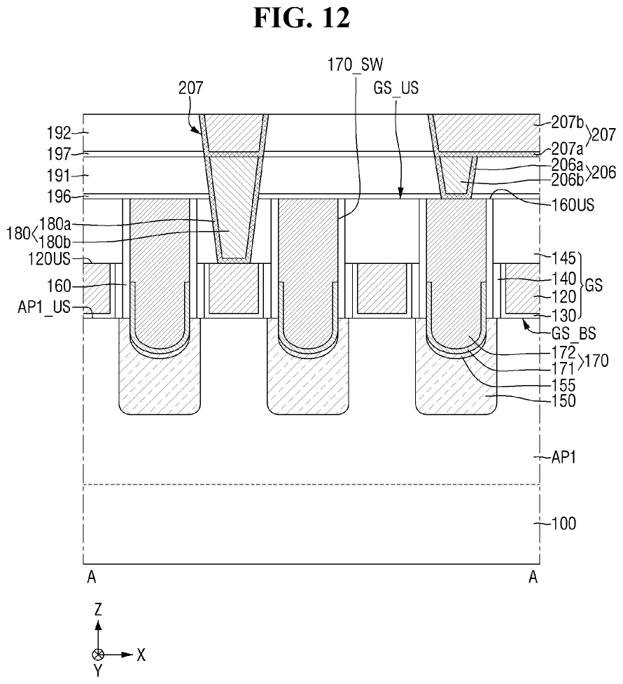

FIG. 12 illustrates a semiconductor device according to embodiments. For ease of description, the following description will focus on differences from the semiconductor device described above with reference to FIGS. 1 through 5.

Referring to FIG. 12, a gate capping layer 145 may not cover an upper surface 160US of a source/drain etch stop layer 160. The gate capping layer 145 may be disposed between portions of the source/drain etch stop layer 160. The upper surface 160US of the source/drain etch stop layer 160 may lie in the same plane as upper surfaces GS_US of gate structures.

The source/drain etch stop layer 160 may extend along side surfaces of each first source/drain contact 170. The source/drain etch stop layer 160 may extend along side surfaces of the gate capping layer 145 and gate spacers 140.

A source/drain contact filling layer 172 may not contact the gate capping layer 145. A second portion 172b of the source/drain contact filling layer 172 may extend along the source/drain etch stop layer 160.

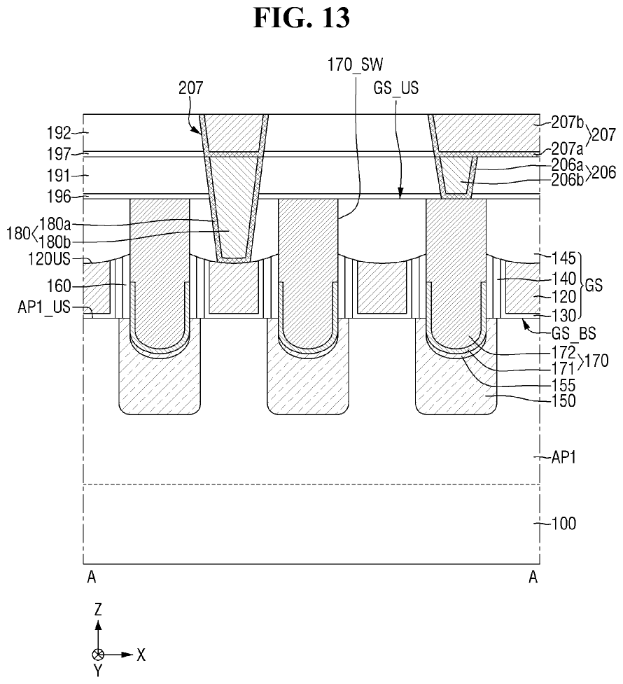

FIG. 13 illustrates a semiconductor device according to embodiments. For ease of description, the following description will focus on differences from the semiconductor device described above with reference to FIGS. 1 through 5.

Referring to FIG. 13, a lower surface of a gate capping layer 145 may be convex toward an upper surface AP1_US of an active pattern. Accordingly, an upper surface of each gate electrode 120 may not be flat. The gate capping layer 145 may contact a source/drain contact filling layer 172. The gate capping layer 145 may cover an upper surface 160US of a source/drain etch stop layer 160. In some embodiments, the gate capping layer 145 may be disposed between portions of the source/drain etch stop layer 160 without covering the upper surface 160US of the source/drain etch stop layer 160.

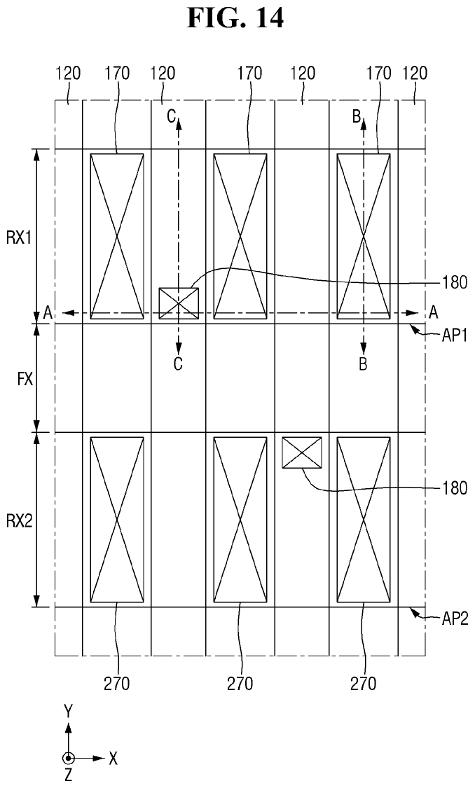

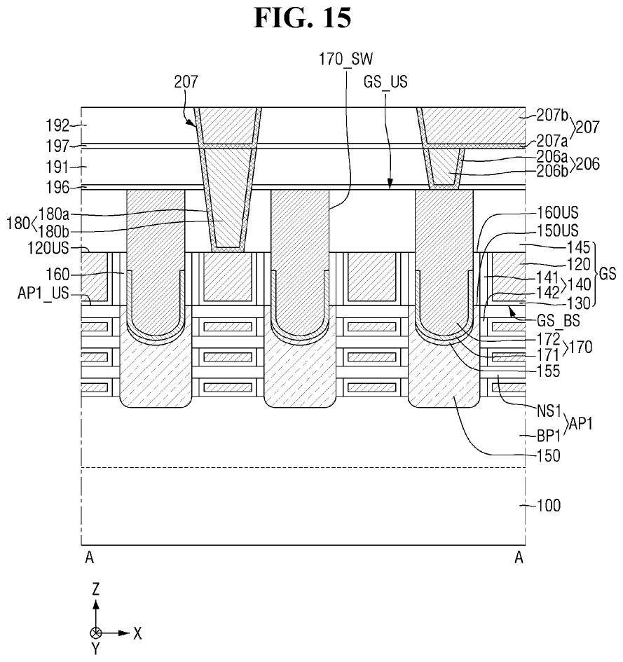

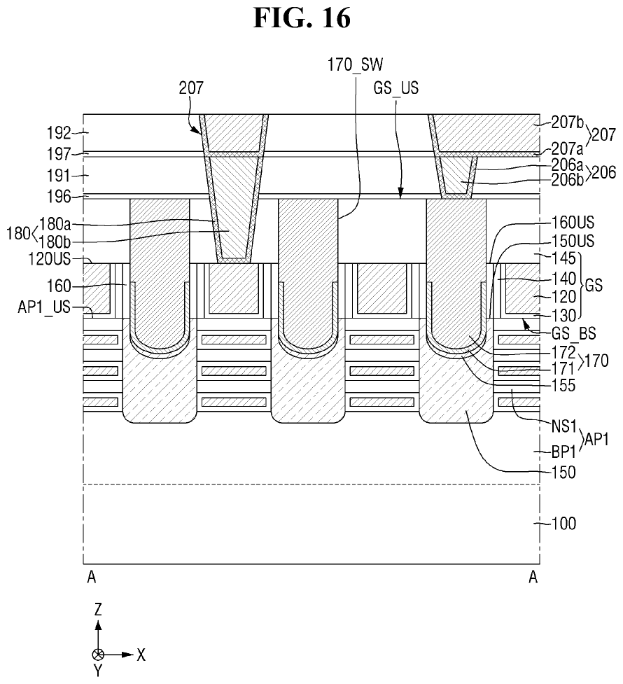

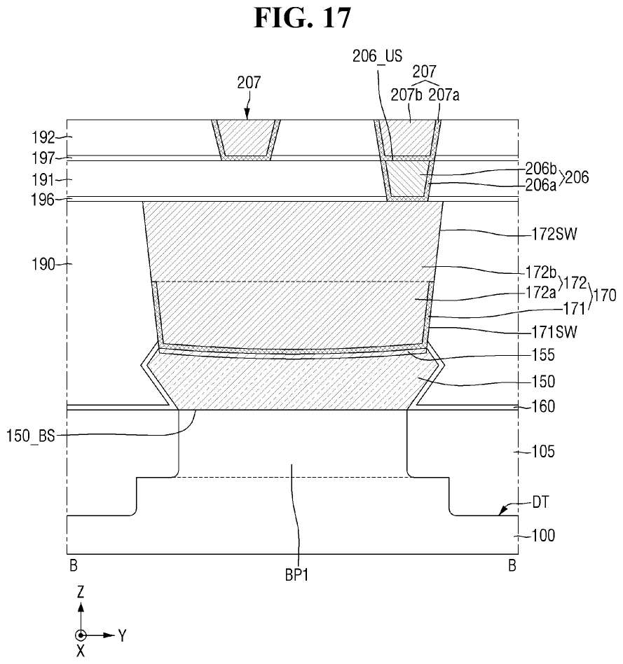

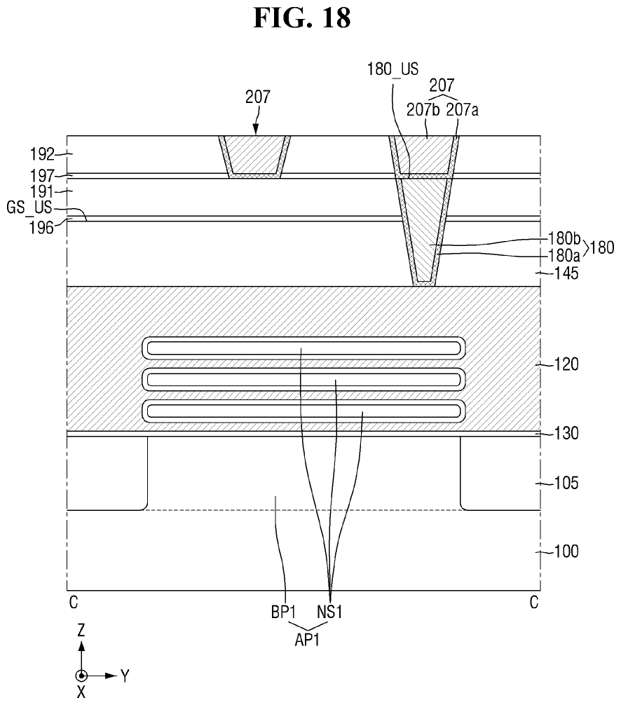

FIGS. 14 through 18 are views illustrating a semiconductor device according to embodiments. FIG. 14 is an example layout view of the semiconductor device according to embodiments. FIGS. 15 and 16 are example cross-sectional views taken along line A-A of FIG. 14. FIG. 17 is a cross-sectional view taken along line B-B of FIG. 14. FIG. 18 is a cross-sectional view taken along line C-C of FIG. 14. For ease of description, the following description will focus on differences from the semiconductor device described above with reference to FIGS. 1 through 5.

Referring to FIGS. 14 through 18, in the semiconductor device according to embodiments, a first active pattern AP1 may include a lower pattern BP1 and sheet patterns NS1.

A second active pattern AP2 may include a lower pattern and sheet patterns.

The lower pattern BP1 may extend along the first direction X. The sheet patterns NS1 may be disposed on the lower pattern BP1 and spaced apart from the lower pattern BP1.

The sheet patterns NS1 may include a plurality of sheet patterns stacked in the third direction Z. Although three sheet patterns NS1 are illustrated, this is an example used for ease of description, and the present disclosure is not limited to this example. An upper surface of an uppermost sheet pattern NS1 among the sheet patterns NS1 may be an upper surface AP1_US of the first active pattern AP1.

The sheet patterns NS1 may be connected to first source/drain patterns 150. The sheet patterns NS1 may be channel patterns used as a channel region of a transistor. For example, the sheet patterns NS1 may be nanosheets or nanowires.

The lower pattern BP1 may include, for example, an elemental semiconductor material such as silicon or germanium. Alternatively, the lower pattern BP1 may include a compound semiconductor such as a group IV-IV compound semiconductor or a group III-V compound semiconductor.

The sheet patterns NS1 may include, for example, an elemental semiconductor material such as silicon or germanium. Alternatively, the sheet patterns NS1 may include a compound semiconductor such as a group IV-IV compound semiconductor or a group III-V compound semiconductor.

A gate insulating layer 130 may extend along an upper surface of the lower pattern BP1 and an upper surface of a field insulating layer 105. The gate insulating layer 130 may surround each of the sheet patterns NS1.

Gate electrodes 120 are disposed on the lower pattern BP1. The gate electrodes 120 cross the lower pattern BP1. Each of the gate electrodes 120 may surround the sheet patterns NS1. Each of the gate electrodes 120 may be disposed between the lower pattern BP1 and a sheet pattern NS1 and between adjacent sheet patterns NS1.

In FIG. 15, each gate spacer 140 may include an outer spacer 141 and an inner spacer 142. The inner spacer 142 may be disposed between the lower pattern BP1 and a sheet pattern NS1 and between adjacent sheet patterns NS1.

In FIG. 16, each gate spacer 140 may include only an outer spacer 141 (see FIG. 15). No inner spacer is disposed between the lower pattern BP1 and a sheet pattern NS1 and between adjacent sheet patterns NS1.

A bottom surface of each first source/drain contact 170 may be located between an upper surface of a lowermost sheet pattern NS1 among the sheet patterns NS1 and a lower surface of the uppermost sheet pattern NS1. The bottom surface of each first source/drain contact 170 may also be located between the upper surface of the uppermost sheet pattern NS1 and the lower surface of the uppermost sheet pattern NS1.

A source/drain contact barrier layer 171 and a source/drain contact filling layer 172 are substantially the same as those described above with reference to FIGS. 1 through 5, and thus a description thereof will be omitted.

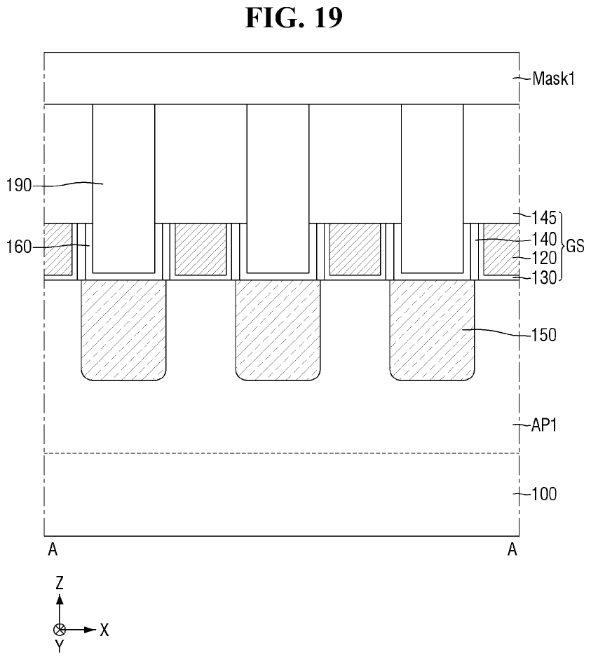

FIGS. 19 through 27 are intermediate views for explaining a method of manufacturing a semiconductor device according to embodiments.

Referring to FIG. 19, source/drain patterns 150 may be formed on a first active pattern AP1.

A source/drain etch stop layer 160 and a first interlayer insulating layer 190 are sequentially formed on the source/drain patterns 150. After the first interlayer insulating layer 190 is formed, gate structures GS may be formed through a replacement metal gate (RMG) process. A gate capping layer 145 may be formed on the source/drain etch stop layer 160.

A first mask layer Mask1 may be formed on the first interlayer insulating layer 190 and the gate structures GS. The first mask layer Mask1 may include, for example, oxide, but the present disclosure is not limited thereto.

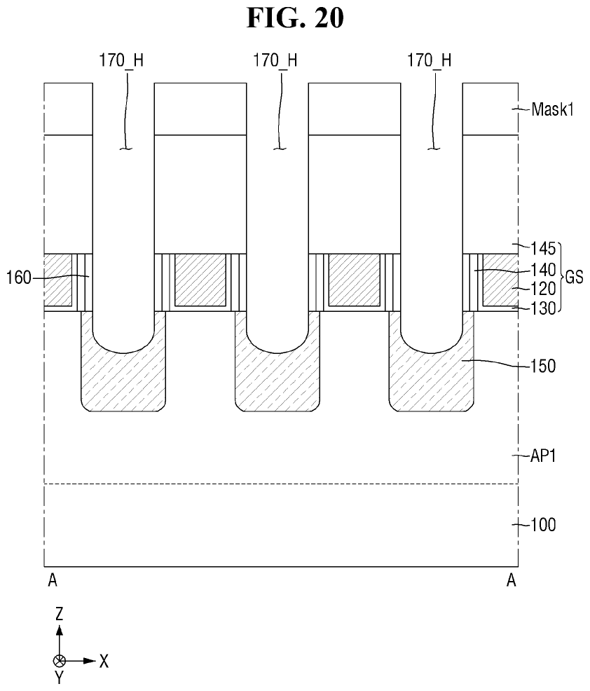

Referring to FIG. 20, source/drain contact holes 170_H passing through the first interlayer insulating layer 190 may be formed.

For example, a photoresist may be formed on the first mask layer Mask1. The photoresist may include patterns for forming the source/drain contact holes 170_H. The source/drain contact holes 170_H may be formed in the first interlayer insulating layer 190 by using the photoresist. The first mask layer Mask1 may be patterned in the process of forming the source/drain contact holes 170_H.

The source/drain contact holes 170_H may expose the source/drain etch stop layer 160 and the source/drain patterns 150. The source/drain contact holes 170_H may pass through the source/drain etch stop layer 160. The source/drain etch stop layer 160 may be partially removed while the source/drain contact holes 170_H are being formed. The source/drain patterns 150 may be partially removed while the source/drain contact holes 170_H are being formed.

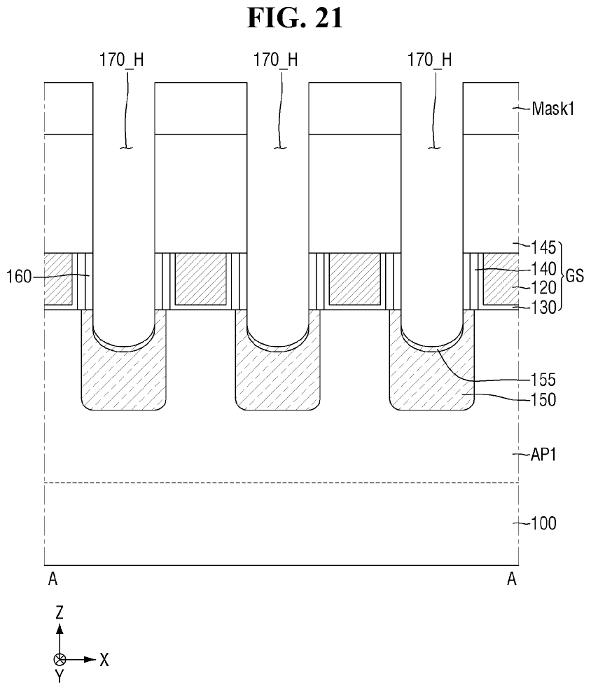

Referring to FIG. 21, a contact silicide layer 155 is formed.

For example, the contact silicide layer 155 may include titanium (Ti). The contact silicide layer 155 may be formed by heat-treating titanium (Ti) on the source/drain pattern 150 exposed in each of the source/drain contact holes 170_H.

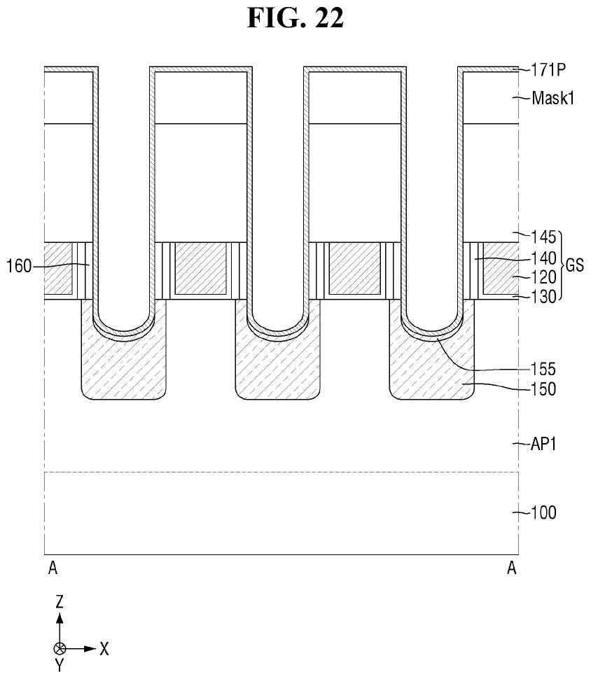

Referring to FIG. 22, a pre-source/drain contact barrier layer 171P is formed.

The pre-source/drain contact barrier layer 171P may extend along inner walls of the source/drain contact holes 170_H (see FIG. 21) and upper surfaces of the contact silicide layers 155. The pre-source/drain contact barrier layer 171P may extend along the gate capping layer 145 and the source/drain etch stop layer 160. The pre-source/drain contact barrier layer 171P may cover the contact silicide layers 155.

Outer walls of the pre-source/drain contact barrier layer 171P may extend along the inner walls of the source/drain contact holes 170_H (see FIG. 21).

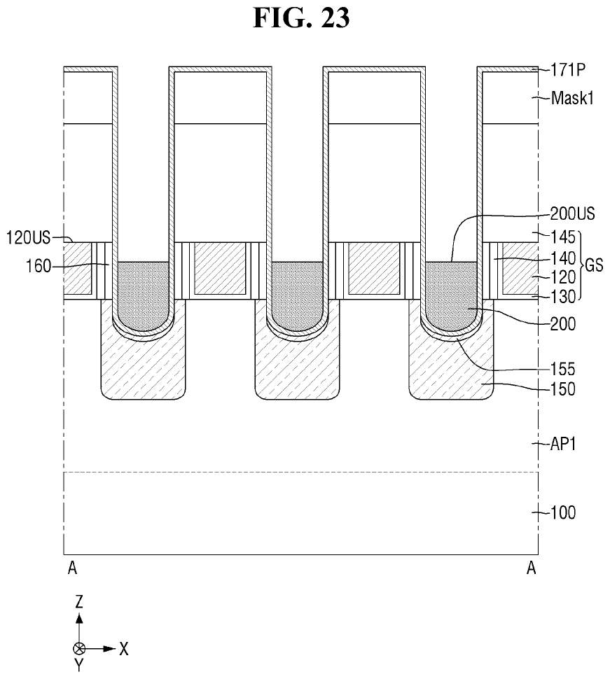

Referring to FIG. 23, a protective layer 200 is formed on the pre-source/drain contact barrier layer 171P.

The protective layer 200 may fill a portion of each of the source/drain contact holes 170_H (see FIG. 21). The protective layer 200 does not entirely fill the source/drain contact holes 170_H (see FIG. 21). The protective layer 200 may cover a portion of the pre-source/drain contact barrier layer 171P. An upper surface 200US of the protective layer 200 may be disposed below an upper surface 120US of each gate electrode.

The pre-source/drain contact barrier layer 171P may include a portion covered by the protective layer 200 and another portion not covered by the protective layer 200.

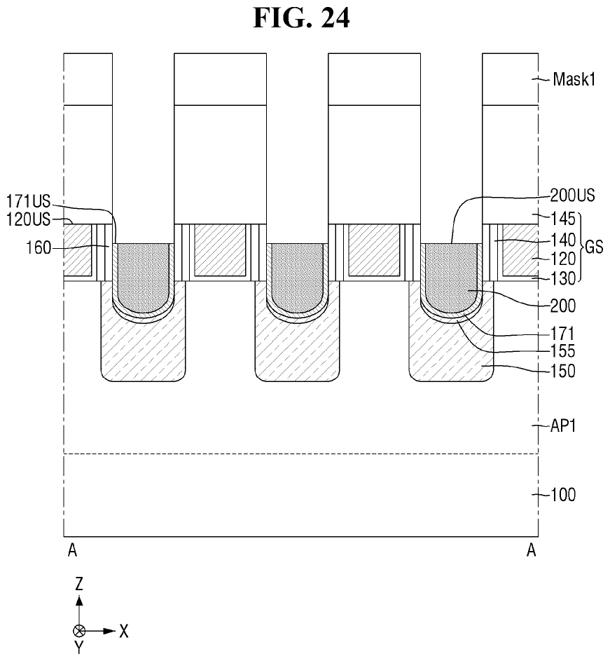

Referring to FIG. 24, the pre-source/drain contact barrier layer 171P is partially removed to form a source/drain contact barrier layer 171.

The pre-source/drain contact barrier layer 171P (see FIG. 23) exposed without being covered by the protective layer 200 may be removed. An uppermost point 171US of the source/drain contact barrier layer 171 may lie in the same plane as the upper surface 200US of the protective layer 200. The uppermost point 171US of the source/drain contact barrier layer 171 may be disposed below the upper surface 120US of each gate electrode.

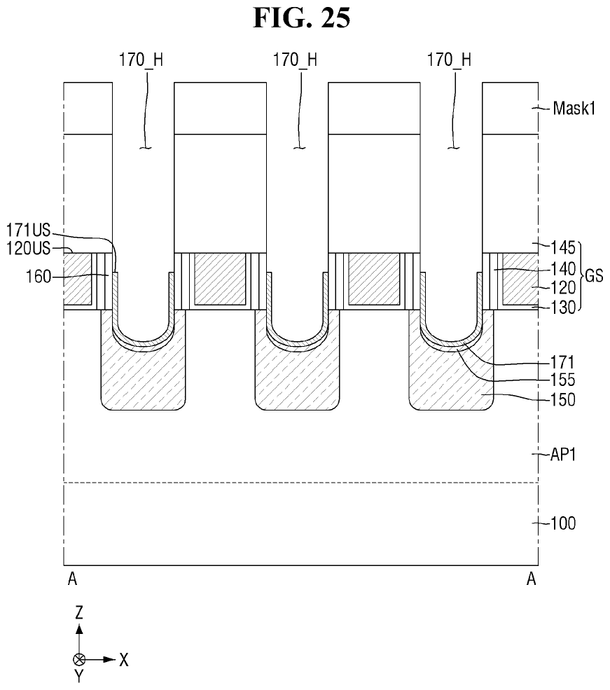

Referring to FIG. 25, the protective layer 200 is removed.

The protective layer 200 (see FIG. 24) may be removed, and the source/drain contact barrier layer 171 may be exposed in each of the source/drain contact holes 170_H.

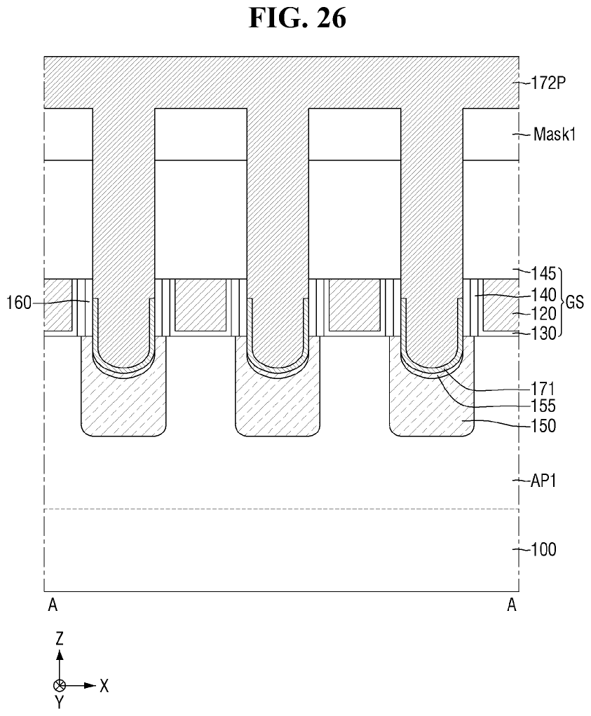

Referring to FIG. 26, a pre-source/drain contact filling layer 172P is formed.

The pre-source/drain contact filling layer 172P may be formed on the source/drain contact barrier layer 171. The pre-source/drain contact filling layer 172P may fill the source/drain contact holes 170_H (see FIG. 25). The pre-source/drain contact filling layer 172P may be formed using physical vapor deposition (PVD).

The pre-source/drain contact filling layer 172P may include a portion surrounded by the source/drain contact barrier layer 171 and a portion extending along the inner walls of the source/drain contact holes 170_H (see FIG. 25) without being surrounded by the source/drain contact barrier layer 171.

A portion of the pre-source/drain contact filling layer 172P which is surrounded by the source/drain contact barrier layer 171 may have a smaller width than another portion extending along the inner walls of the source/drain contact holes 170_H (see FIG. 25) without being surrounded by the source/drain contact barrier layer 171.

Outer walls of the pre-source/drain contact filling layer 172P may extend along the inner walls of the source/drain contact holes 170_H (see FIG. 25). The outer walls of the pre-source/drain contact filling layer 172P and the outer walls of the source/drain contact barrier layer 171 may extend along the inner walls of the source/drain contact holes 170_H (see FIG. 25) and may lie in the same plane.

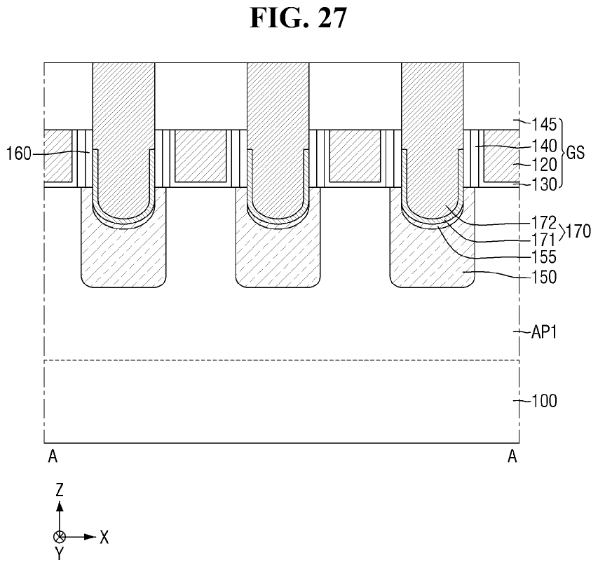

Referring to FIG. 27, a portion of the pre-source/drain contact filling layer 172P, the first mask layer Mask1, and a portion of the gate capping layer 145 are removed to form first source/drain contacts 170.

Next, referring to FIG. 2, a gate contact 180, a via plug 206, a second etch stop layer 197, a third interlayer insulating layer 192, and wiring lines 207 are formed.

While aspects of embodiments have been particularly shown and described, it will be understood that various changes in form and details may be made therein without departing from the spirit and scope of the following claims.

What is claimed is:

1. A semiconductor device comprising:
an active pattern extending in a first direction;
a gate structure comprising a gate electrode extending in a second direction and a gate spacer on the active pattern, wherein the gate electrode and the gate spacer are spaced apart from each other in the first direction;
a source/drain pattern on the active pattern;
a contact barrier layer on the source/drain pattern; and
a contact filling layer on the contact barrier layer,
wherein an uppermost point of the contact barrier layer is between an upper surface of the contact filling layer and a lower surface of the contact filling layer, and outer walls of the contact barrier layer and outer walls of the contact filling layer extend along a common plane.

2. The semiconductor device of claim 1, wherein the contact filling layer comprises:
a first portion having a first width along the first direction, wherein the first portion is surrounded by the contact barrier layer; and
a second portion on the first portion, not overlapping the contact barrier layer in the first direction, and having a second width along the first direction greater than the first width.

3. The semiconductor device of claim 1, further comprising a silicide layer between the source/drain pattern and the contact barrier layer, wherein the contact filling layer does not contact the silicide layer.

4. The semiconductor device of claim 1, wherein the upper surface of the contact filling layer and an uppermost surface of the gate structure extend along a common plane.

5. The semiconductor device of claim 1, wherein the contact barrier layer comprises titanium nitride, and the contact filling layer comprises tungsten.

6. The semiconductor device of claim 1, wherein the uppermost point of the contact barrier layer is between an upper surface of the gate electrode and the lower surface of the contact filling layer.

7. The semiconductor device of claim 1, wherein the uppermost point of the contact barrier layer is between the upper surface of the gate electrode and the upper surface of the upper surface of the contact filling layer.

8. The semiconductor device of claim 1, wherein the contact barrier layer does not comprise silicon (Si) and boron (B).

9. The semiconductor device of claim 1, wherein the upper surface of the gate electrode is flat.

10. The semiconductor device of claim 1, wherein the gate structure further comprises a gate capping layer on the gate electrode, and the contact filling layer contacts the gate capping layer.

11. The semiconductor device of claim 10, further comprising an etch stop layer on a side surface of the gate spacer on the source/drain pattern, wherein the gate capping layer covers an upper surface of the etch stop layer.

12. The semiconductor device of claim 1, wherein the contact barrier layer entirely surrounds the lower surface of the contact filling layer.

13. A semiconductor device comprising:
an active pattern extending in a first direction;
a gate structure comprising a gate electrode extending in a second direction and a gate spacer on the active pattern, wherein the gate electrode and the gate spacer are spaced apart from each other in the first direction;
a source/drain pattern on the active pattern;
a contact barrier layer on the source/drain pattern; and
a contact filling layer on the contact barrier layer,
wherein the contact filling layer comprises a first portion surrounded by the contact barrier layer and a second portion on the first portion that does not overlap the contact barrier layer in the first direction, and
wherein a first width along the first direction of the first portion is smaller than a second width along the first direction of the second portion, and outer walls of the contact barrier layer and outer walls of the second portion of the contact filling layer extend along a common plane.

14. The semiconductor device of claim 13, wherein an uppermost point of the contact barrier layer is between an upper surface of the gate electrode and a lower surface of the contact filling layer.

15. The semiconductor device of claim 13, wherein the contact barrier layer comprises titanium nitride, and the contact filling layer comprises tungsten.

16. The semiconductor device of claim 13, further comprising a silicide layer between the source/drain pattern and the contact barrier layer.

17. The semiconductor device of claim 16, wherein a lower surface of the silicide layer is between an upper surface of the source/drain pattern and a lower surface of the source/drain pattern.

18. The semiconductor device of claim 13, wherein an upper surface of the contact filling layer and an uppermost surface of the gate structure extend along a common plane.

19. The semiconductor device of claim 13, wherein a grain size of the first portion is smaller than a grain size of the second portion.

20. A semiconductor device comprising:
an active pattern extending in a first direction;
a gate structure comprising a gate electrode extending in a second direction and a gate spacer on the active pattern, wherein the gate electrode and the gate spacer are spaced apart from each other in the first direction;
a source/drain pattern on the active pattern;
a silicide layer on the source/drain pattern;
a contact barrier layer on the silicide layer; and
a contact filling layer on the contact barrier layer,
wherein the contact filling layer comprises a first portion surrounded by the contact barrier layer and a second portion on the first portion that does not overlap the contact barrier layer in the first direction,
wherein a first width of the first portion along the first direction is smaller than a second width of the second portion along the first direction,
wherein outer walls of the contact barrier layer and outer walls of the second portion of the contact filling layer extend along a common plane,
wherein the contact barrier layer comprises titanium nitride and the contact filling layer comprises tungsten, and
wherein an uppermost point of the contact barrier layer is between an upper surface of the gate electrode and a lower surface of the contact filling layer.
